(19) United States
(12) Patent Application Publication
(10) Pub. No.: US 2008/0054370 A1
(43) Pub. Date: Mar. 6, 2008

(54) Semiconductor device and method of fabricating the same

(75) Inventors: Shinya Naito, Anpachi-gun (JP); Hideaki Fujiwara, Hashima-shi (JP); Toru Dan, Gifu-shi (JP)

Correspondence Address: MCDERMOTT WILL & EMERY LLP, 600 13TH STREET, N.W., WASHINGTON, DC, 20005-3096, US

(73) Assignee: SANYO ELECTRIC CO., LTD.

(21) Appl. No.: 11/896,163

(22) Filed: Aug. 30, 2007

(30) Foreign Application Priority Data
Aug. 31, 2006 (JP) JP2006-235706
Jul. 25, 2007 (JP) JP2007-193065

(51) Int. Cl. H01L 27/06; H01L 21/331; H01L 29/732; H01L 21/8249

(52) U.S. Cl. 257/378; 257/588; 438/234; 438/343; 257/E21.375; 257/E21.696; 257/E29.183; 257/E27.016

(57) ABSTRACT

A semiconductor device include an emitter layer, an emitter electrode containing a metal-semiconductor compound of a metal and a semiconductor, formed on a surface of the emitter layer, and a first reaction suppression layer formed between the emitter layer and the emitter electrode and suppressing permeation of the metal diffused from the emitter electrode.

### CROSS-REFERENCE TO RELATED APPLICATIONS

The priority application numbers JP2006-235706, Method of Fabricating a Semiconductor Device, Aug. 31, 2006, Shinya Naito, Hideaki Fujiwara, Toru Dan, JP2007-193065, Semiconductor Device and Method of Fabricating the Same, Jul. 25, 2007, Shinya Naito, Hideaki Fujiwara, Toru Dan, upon which this patent application is based is hereby incorporated by reference.

### BACKGROUND OF THE INVENTION

1. Field of the Invention

The present invention relates to a semiconductor device and a method of fabricating the same, and more particularly, it relates to a semiconductor device comprising a silicide film and a method of fabricating the same.

2. Description of the Background Art

A semiconductor device comprising a silicide film is known in general.

In a conventional semiconductor device, cobalt (Co) or titanium (Ti) is formed on a surface of an emitter electrode of a bipolar transistor and thermal treatment is performed, thereby forming a cobalt silicide film or a titanium silicide film. A metal-semiconductor compound obtained by chemical reaction (silicidation) of a metal and silicon is employed as the emitter electrode, whereby an emitter resistance can be reduced and a cutoff frequency can be increased. Further, the silicidation proceeds to an interface between the emitter electrode and the emitter layer, whereby the emitter resistance can be further reduced and the cutoff frequency can be further increased.

In the conventional semiconductor device, however, when the silicidation of the emitter electrode proceeds to the interface between the emitter electrode and the emitter layer, silicidation disadvantageously proceeds to the emitter layer, further to a base layer since the emitter electrode and the emitter layer are in contact with each other. Thus, the emitter layer and the base layer short out, and hence a transistor goes out. Also when the emitter layer is not entirely but partially silicided, a depth in a vertical direction with respect to a substrate of the emitter layer is decreased and hence the gradient of carrier concentration between the emitter layer and the base layer is increased. This causes increase in a base current, and the amplification factor of the transistor is reduced. Consequently, performance of the transistor is deteriorated.

### SUMMARY OF THE INVENTION

A semiconductor device according to a first aspect of the present invention comprises an emitter layer, an emitter electrode containing a metal-semiconductor compound of a metal and a semiconductor, formed on a surface of the emitter layer, and a first reaction suppression layer formed between the emitter layer and the emitter electrode and suppressing permeation of the metal diffused from the emitter electrode.

A method of fabricating a semiconductor device according to a second aspect of the present invention comprises steps of forming an emitter layer, forming a first reaction suppression layer suppressing permeation of a metal on a surface of the emitter layer, and forming an emitter electrode containing a metal-semiconductor compound of a metal and a semiconductor on a surface of the first reaction suppression layer after forming the first reaction suppression layer.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross sectional view of a bipolar transistor according to a first embodiment of the present invention;

FIGS. 2 to 11 are cross sectional views for illustrating a process of fabricating the bipolar transistor according to the first embodiment of the present invention;

FIG. 12 is a cross sectional view of a bipolar transistor according to a second embodiment of the present invention;

FIG. 13 is a cross sectional view of a semiconductor device according to a third embodiment of the present invention;

FIG. 14 is a cross sectional view for illustrating a process of fabricating the semiconductor device according to the third embodiment of the present invention;

FIG. 15 is a cross sectional view of a semiconductor device according to a fourth embodiment of the present invention;

FIG. 16 is a cross sectional view for illustrating a process of fabricating the semiconductor device according to the fourth embodiment of the present invention; and

FIG. 17 is a cross sectional view of a semiconductor device according to a fifth embodiment of the present invention.

### DESCRIPTION OF THE PREFERRED EMBODIMENTS

Embodiments of the present invention will be hereinafter described with reference to the drawings.

### First Embodiment

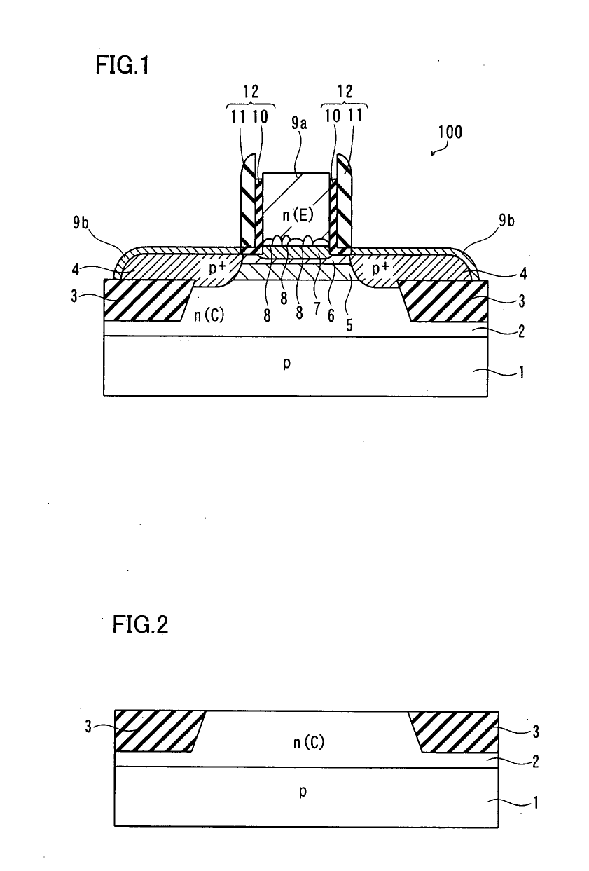

In a bipolar transistor 100, an n-type collector layer 2 is formed on a surface of a p-type silicon substrate 1 as shown in FIG. 1. Element isolation regions 3 employing STI (shallow trench isolation) are formed on a surface of the collector layer 2. A pair of p⁺-type diffusion layers 4 are formed on the surface of the collector layer 2 at a prescribed interval. A SiGe layer 5 containing silicon germanium (SiGe) employed as a base region is formed in a region held between the pair of diffusion layers 4 on the surface of the collector layer 2. A p-type silicon film 6 is formed on a surface of the SiGe layer 5.

An n-type diffusion layer 7 is formed on a surface of the silicon film 6. The diffusion layer 7 is an example of the “emitter layer” in the present invention. Reaction suppression layers 8 containing titanium nitride (TiN) are formed on a surface of the diffusion layer 7. The reaction suppression layer 8 is an example of the “first reaction suppression layer” in the present invention.

A cobalt silicide film 9a employed as an emitter electrode is formed on surfaces of the reaction suppression layers 8. The cobalt silicide film 9a is an example of the “emitter electrode” in the present invention. A silicon nitride film 10 is formed on prescribed regions of the silicon film 6 and the diffusion layer 7 and side surfaces of the reaction suppression layers 8 and the cobalt silicide film 9a. A silicon oxide film 11 is formed on a surface of the silicon nitride film 10. The silicon nitride film 10 and the silicon oxide film 11 constitute a side wall film 12. The cobalt silicide films 9b are formed on surfaces of the diffusion layers 4.

A process of fabricating the bipolar transistor 100 according to the first embodiment of the present invention will be described with reference to FIGS. 2 to 11.

As shown in FIG. 2, the element isolation regions 3 employing STI are formed on the surface of the silicon substrate 1 by lithography and etching. Then, the collector layer 2 is formed by ion-implanting phosphorus (P) into a prescribed region of the silicon substrate 1 from above a surface formed with the element isolation regions 3 at implantation energy of about 500 keV to about 4000 keV and a dose of about 3.0×10¹³ cm⁻² to about 3.0×10¹⁵ cm⁻² and performing thermal treatment at 1000° C., for example.

In place of the aforementioned ion implantation step and thermal treatment step, the element isolation regions 3 such as STI are formed by lithography and etching after forming the collector layer 2 by a silicon epitaxial layer doped with an n-type impurity on the silicon substrate 1.

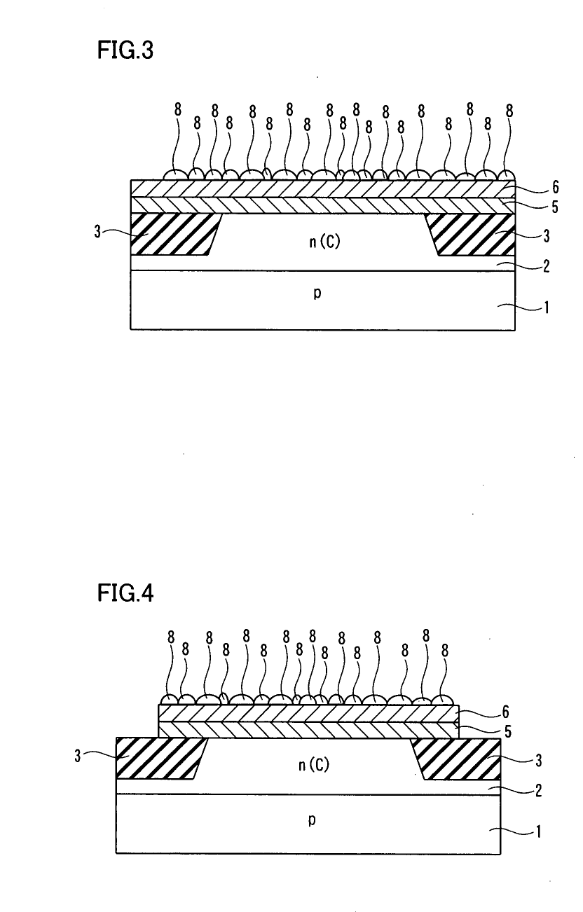

As shown in FIG. 3, the SiGe layer 5 having a thickness of about 40 nm and the silicon film 6 having a thickness of about 40 nm are successively formed on the surfaces of the collector layer 2 and the element isolation regions 3 by low pressure CVD (chemical vapor deposition). The SiGe layer 5 and the silicon film 6 are doped with boron (B) at a concentration of about 1.0×10¹⁹ cm⁻³.

The concentration of Ge in the SiGe layer 5 may be constant in the SiGe layer 5 or may be gradually increase from a side in contact with the silicon film 6 of the SiGe layer 5 toward a side in contact with the collector layer 2 of the SiGe layer 5. At this time, the concentration of Ge is preferably substantially 0% on the side in contact with the silicon film 6 of the SiGe layer 5, while the concentration of Ge is preferably substantially about 15% to about 20% on the side in contact with the collector layer 2 of the SiGe layer 5. The concentration of Ge gradually increases from the side in contact with the silicon film 6 of the SiGe layer 5 toward the side in contact with the collector layer 2 of the SiGe layer 5, whereby slope of a potential capable of accelerating electrons is formed, and hence the transit time of electrons moving in the SiGe layer 5 can be reduced. Consequently, the bipolar transistor 100 can be operated at a high speed.

The reaction suppression layers 8 containing titanium nitride (TiN) having a thickness of not more than about 20 nm, preferably not more than about 10 nm are formed on the surface of the silicon film 6 by low pressure CVD. The composition ratio of titanium (Ti) in TiN is about 45% to about 55%. The composition ratio is preferably about 50%. In the reaction suppression layers 8, a surface of a thin film is not flat and is preferably constituted by a polycrystalline or nanocrystalline material formed by crystal grains each having a grain size of about 1 nm to about 10 nm. More particularly, the polycrystalline or nanocrystalline material is more preferably formed by crystal grains each having a grain size of about 1 nm to about 3 nm. The reaction suppression layers 8 are so formed as to be in contact with the silicon film 6 and cover at least a part of the surface of the silicon film 6 with the polycrystalline material.

As shown in FIG. 4, a resist film is provided by lithography and thereafter the resist film is employed as a mask for dry etching, thereby removing prescribed regions of the SiGe layer 5 employed as a base layer, the silicon film 6 employed as the emitter layer and the reaction suppression layers 8.

As shown in FIG. 5, a polycrystalline silicon film 21 having a thickness of about 200 nm and a silicon nitride film 22 having a thickness of about 100 nm are successively formed on the surfaces of the element isolation regions 3 and the reaction suppression layers 8 by low pressure CVD. The polycrystalline silicon film 21 is doped with arsenic (As) or phosphorus (P) at a concentration of about 1.0×10²⁰ cm⁻³, for example, thereby forming an n-type polycrystalline silicon film.

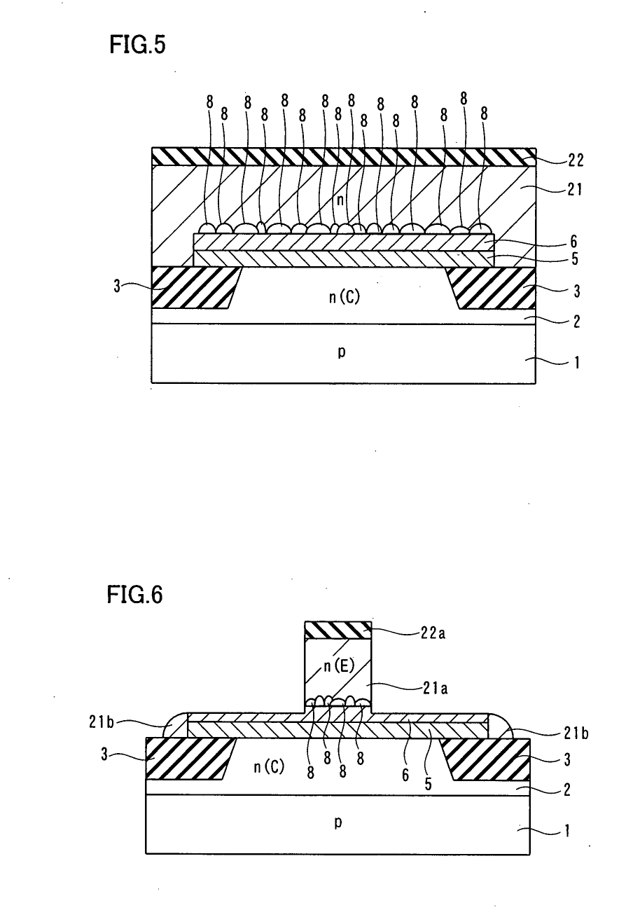

As shown in FIG. 6, a resist film is provided by lithography and thereafter the silicon nitride film 22, the polycrystalline silicon film 21 and the silicon film 6 are patterned by dry etching. At this time, the dry etching is finished in a state where the silicon film 6 remains also on the surface of the SiGe layer 5 without completely removing the silicon film 6. Thus, the silicon film 6 is so formed that the cross section thereof has a projecting portion. At this time, the polycrystalline silicon film 21 is processed into a polycrystalline silicon film 21a serving as the emitter electrode and side wall films 21b formed on side surfaces of the SiGe layer 5 and the silicon film 6. The silicon nitride film 22 is processed into a silicon nitride film 22a, and functions as a mask when etching the polycrystalline silicon film 21a in a subsequent step.

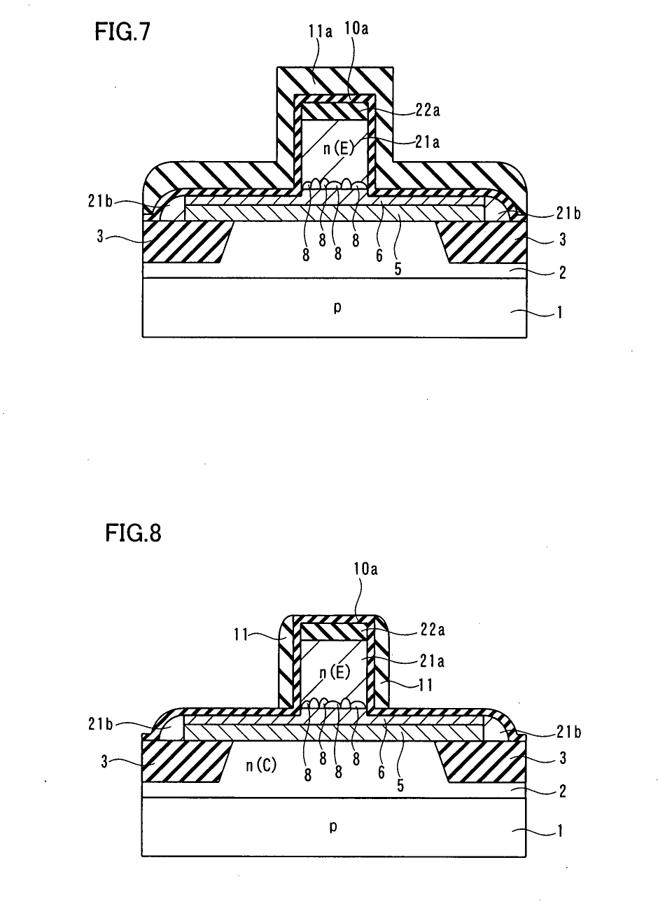

As shown in FIG. 7, the silicon nitride film 10a having a thickness of about 10 nm is so formed as to cover an overall surface by low pressure CVD. The silicon nitride film 10a is formed by thermal-treating a gas mixture of dichlorosilane (SiH₂Cl₂) and ammonia (NH₃) at a temperature of about 700° C. The silicon oxide film 11a having a thickness of about 200 nm is formed on a surface of the silicon nitride film 10a. The silicon oxide film 11a is formed by thermal-treating a gas mixture of tetraethoxysilane (TEOS) and oxygen (O₂) at a temperature of about 720° C.

As shown in FIG. 8, an overall surface of the silicon oxide film 11a is etched back by dry etching, thereby forming the silicon oxide film 11 around the projecting portion of the silicon film 6, the polycrystalline silicon film 21a and the silicon nitride film 22a. In this dry etching, the etching selection ratio of the silicon nitride film 10a to the silicon oxide film 11a is 10 or more, and hence the silicon nitride film 10a is not removed by etching even in view of variations in production for process of the silicon oxide film 11. Thus, damage of etching by dry etching does not affect the silicon film 6, and the SiGe layer 5 having a film thickness as designed can be formed.

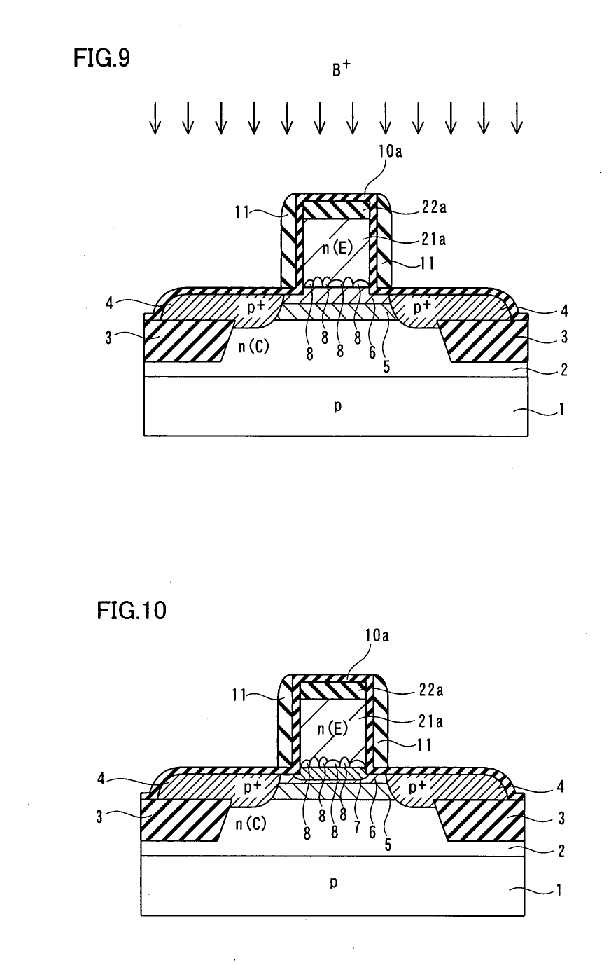

As shown in FIG. 9, the pair of diffusion layers 4 are so formed as to hold the SiGe layer 5 therebetween by implanting BF₂ from the surfaces of the silicon nitride film 10a and the silicon oxide film 11 at implantation energy of about 1 keV to about 30 keV and a dose of about 1.0×10¹⁴ cm⁻² to about 5.0×10¹⁵ cm⁻² by ion implantation, for example. In the implantation conditions, boron ion (B⁺) does not pass through the silicon nitride film 22a having a thickness of about 100 nm on the polycrystalline silicon film 21a, and hence boron ion (B⁺) is not implanted into the polycrystalline silicon film 21a.

As shown in FIG. 10, the n-type impurity of the polycrystalline silicon film 21a is diffused in the silicon film 6 by performing thermal treatment at about 1050° C. for about 5 to about 30 seconds by RTA (rapid thermal anneal), thereby forming the diffusion layer 7. At this time, the atomic radius of the impurity (boron) is small so as to pass through the reaction suppression layers 8 formed by the crystal grains of titanium nitride (TiN), and hence the impurity can be pass through the reaction suppression layers 8. Thus, an emitter-base junction by the diffusion layers 4 is completed.

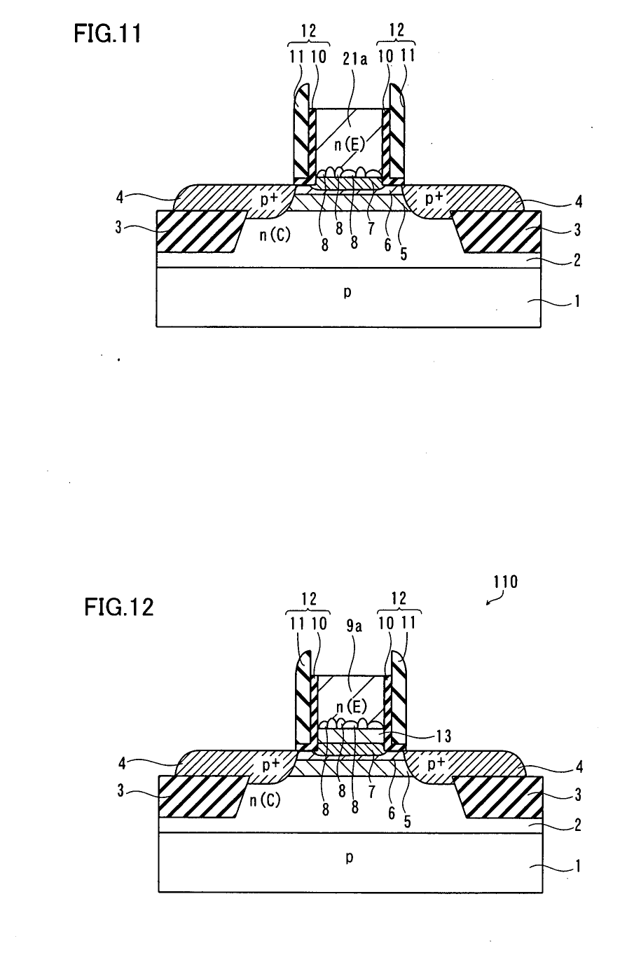

As shown in FIG. 11, the silicon nitride film 10a on the prescribed surfaces of the element isolation regions 3, the diffusion layers 4, the silicon nitride film 22a (see FIG. 10) and a collector electrode (not shown) is removed by performing a treatment using phosphoric acid at a temperature of about 160° C. for about 20 minutes. The silicon nitride film 22a on the polycrystalline silicon film 21a is removed in a similar manner, whereby the side wall film 12 constituted by the silicon nitride film 10 and the silicon oxide film 11 is formed. Therefore, the silicon nitride film 10 is formed only between the silicon oxide film 11 and the silicon film 6, the diffusion layer 7 and the polycrystalline silicon film 21a. Thus, the silicon nitride film 10 is positioned between the silicon oxide film 11 and the silicon film 6, whereby boron (B) employed as the impurity contained in the silicon film 6 can be inhibited from diffusing into the silicon oxide film 11 when performing thermal treatment. Consequently, the prescribed impurity concentration of boron (B) can be maintained in the silicon film 6, whereby the bipolar transistor 100 having characteristics as designed can be obtained.

As shown in FIG. 1, cobalt (Co) layer (not shown) is formed on the surfaces of the polycrystalline silicon film 21a and the diffusion layers 4 and thereafter thermal treatment is performed, thereby forming the cobalt silicide films 9a and 9b. The cobalt silicide film 9a is a metal-semiconductor compound of polycrystalline silicon and cobalt and serves as a metal emitter electrode. The film thickness of cobalt employed for silicidation is set to 200 nm or more, whereby the polycrystalline silicon film 21a having a film thickness of about 200 nm can be completely silicided. Excessive cobalt is removed by wet etching.

The sheet resistance values of the cobalt silicide films 9a and 9b are about 5 Ω/□ and is extremely low value as compared with the sheet resistance value of a conventional SiGe layer 5 (diffusion layers 4) which is about 100 Ω/□. Thus, a parasitic resistance generated in base electrode (not shown) linked to an inner base layer (portions having the same width as that of the diffusion layer 7 and located under the diffusion layer 7 in the SiGe layer 5 and the silicon film 6) and an outer base layer (base layer other than the inner base layer) can be reduced.

Thereafter contact portions of the collector electrode, the base electrode, and the emitter electrode are opened after depositing an interlayer dielectric film such as plasma TEOS film on a surface of the bipolar transistor 100, although not shown. A barrier metal layer containing Ti or the like, and a conductive layer containing Al or Al alloy are formed, thereby forming the bipolar transistor 100 according to the first embodiment.

According to the first embodiment, as hereinabove described, the reaction suppression layers 8 suppressing permeation of cobalt diffusing between the diffusion layer 7 and the cobalt silicide film 9a from the cobalt silicide film 9a is provided, whereby the reaction suppression layers 8 formed by the crystal grains of titanium nitride (TiN) can suppress permeation of cobalt (Co) having a large atomic radius and hence diffusion of the cobalt into the diffusion layer 7 can be suppressed. Thus, the silicidation can be inhibited from proceeding to the diffusion layer 7. Also when a grain boundary is wide, the area where Co diffuses below Tin can be reduced due to existence of TiN. Thus, it is possible to ensure the depth in a direction of the silicon substrate 1 of the diffusion layer 7, whereby the amplification factor of the bipolar transistor 100 can be secured. Consequently, the resistance of the diffusion layer 7 can be reduced, whereby a cutoff frequency can be increased.

According to the first embodiment, as hereinabove described, the emitter electrode (cobalt silicide film 9a) is formed by cobalt silicide (metal silicide) employed as a metal-semiconductor compound, whereby the contact resistance of the emitter electrode and the emitter layer (diffusion layer 7) can be easily reduced.

According to the first embodiment, as hereinabove described, the reaction suppression layers 8 are formed by titanium nitride (TiN), whereby titanium nitride employed as a metal nitride has a high melting point, and the substance itself is chemically stable. Therefore, chemical reaction between the cobalt silicide film 9a and the reaction suppression layers 8 can be inhibited from taking place. Thus, diffusion of cobalt into the diffusion layer 7 and silicidation of the diffusion layer 7 can be suppressed.

According to the first embodiment, as hereinabove described, the reaction suppression layers 8 are formed by a polycrystalline or nanocrystalline material whereby control of size of the crystal grains can inhibit cobalt having a large atomic radius from passing through the reaction suppression layers 8 and boron having a small atomic radius can be passed through the reaction suppression layers 8. Therefore, diffusion of boron into the silicon film 6 and silicidation of the cobalt silicide film 9a can be simultaneously performed. Thus, time for producing the bipolar transistor 100 can be reduced.

### Second Embodiment

In a bipolar transistor 110 according to a second embodiment, as shown in FIG. 12, a polycrystalline silicon film 13 is formed between a diffusion layer 7 and a reaction suppression layers 8 dissimilarly to the aforementioned first embodiment. The polycrystalline silicon film 13 is an example of the “second semiconductor layer” in the present invention. Arsenic (As) employed as an n-type impurity is implanted into the polycrystalline silicon film 13, and arsenic contained in the polycrystalline silicon film 13 is diffused into the silicon film 6 by applying thermal treatment. Thus, the diffusion layer 7 is formed.

The remaining structure of the second embodiment is similar to that of the aforementioned first embodiment.

According to the second embodiment, as hereinabove described, the polycrystalline silicon film 13 is formed between the diffusion layer 7 and the reaction suppression layers 8, whereby arsenic contained in the polycrystalline silicon film 13 can be diffused into the silicon film 6 without passing through the reaction suppression layers 8 to form the diffusion layer 7. Therefore, arsenic can be accurately diffused into the diffusion layer 7 as compared with a case in which the diffusion layer 7 is formed through the reaction suppression layers 8. Thus, the depth of the diffusion layer 7 (emitter layer) can be ensured, whereby a current amplification factor affected by the depth of the diffusion layer 7 can be improved. Consequently, a high doped base layer which achieves a low base resistance can be employed, whereby performance of the bipolar transistor 110 can be improved.

### Third Embodiment

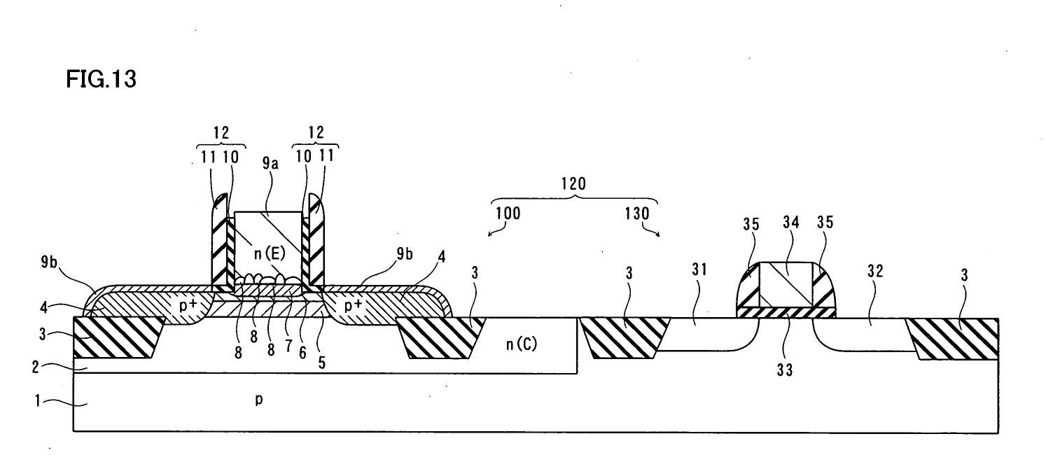

In a semiconductor device 120 according to a third embodiment, as shown in FIG. 13, a field-effect transistor 130 is formed on the same substrate on which a bipolar transistor 100 is formed dissimilarly to the aforementioned first embodiment.

In the semiconductor device 120, element isolation regions 3 employing STI, for isolating the bipolar transistor 100 and the field-effect transistor 130 are formed on a surface of a silicon substrate 1. Impurity regions 31 and 32 serving as source/drain of the field-effect transistor 130 are so formed on the surface of the silicon substrate 1 at a prescribed interval, as to hold a channel region therebetween.

A gate insulating film 33 including a material containing a compound of Si, Al, Ti, Hf and N is formed on a region formed with the field-effect transistor 130 on the surface of the silicon substrate 1. A gate electrode 34 containing a compound of a metal such as Ti, Co or Ni and a semiconductor such as Si or Ge is formed on a surface of the gate insulating film 33. Side wall insulating films 35 are formed on side surfaces of the gate electrode 34.

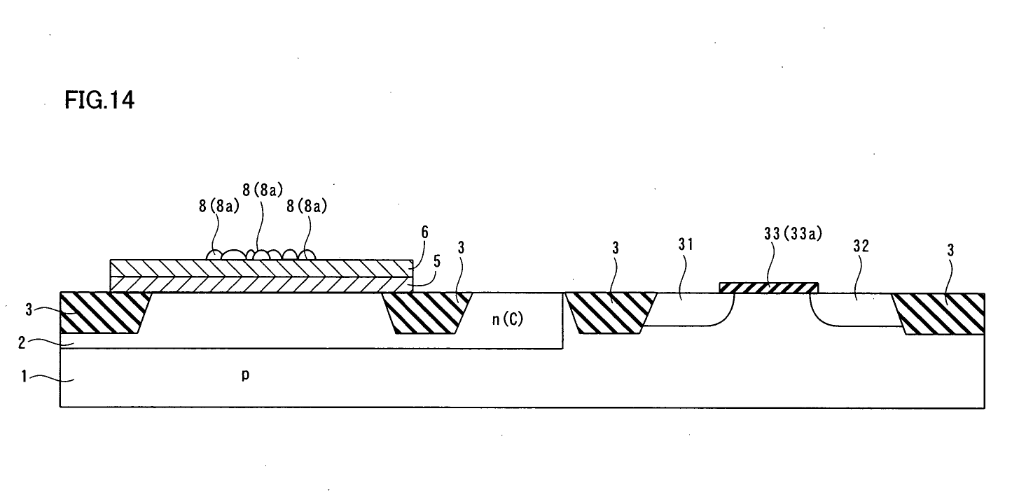

Nitridation of reaction suppression layers 8 and the gate insulating film 33 and silicidation of cobalt silicide film 9a and the gate electrode 34 will be now described with reference to FIG. 14.

As shown in FIG. 14, a polycrystalline or nanocrystalline titanium (Ti) 8a is formed on a surface of the silicon film 6 by sputtering. An insulating film 33a containing Hf for example is formed on a prescribed region of the silicon film 6 and prescribed regions of the impurity regions 31 and 32 by sputtering. An insulating film containing Si may be formed in place of the insulating film 33a containing Hf.

The titanium layer 8a and the insulating film 33a are nitrided by nitridation treatment using ammonia or N₂O or nitridation treatment using plasma. Thus, the reaction suppression layers 8 containing titanium nitride (TiN) and the gate insulating film 33 containing HfON are formed by the same nitridation step. When the insulating film containing of Si is employed in place of the insulating film 33a containing of Hf, the gate insulating film 33 containing SiON is formed. The nitridation treatment performed on the gate insulating film 33 and the nitridation treatment performed on the reaction suppression layers 8 are carried out in the same step, whereby the number of steps can be reduced and the cost can be reduced.

As shown in FIG. 13, the cobalt silicide film 9a (emitter electrode) of the bipolar transistor 100 and the gate electrode 34 of the field-effect transistor 130 are formed on surfaces of the polycrystalline silicon film 21a (see FIG. 11) and a gate electrode (not shown) not yet silicided, in the same step by forming cobalt and performing thermal treatment, for example.

In the cobalt silicide film 9a of the bipolar transistor 100, an impurity rapidly diffuses from a surface to the reaction suppression layers 8 and hence the concentration of the impurity is high and uniform. Diffusion of the impurity are suppressed in the diffusion layer 7 (emitter layer) below the reaction suppression layers 8, and hence the concentration of the impurity is high in the vicinity of the reaction suppression layers 8 and becomes smaller toward a side closer to a base layer (the SiGe layer 5 and the silicon film 6). The concentration of the impurity in the diffusion layer 7 is low, whereby the diffusion rate of the impurity is reduced as the concentration of the impurity is low. Thus, variations in device characteristic with respect to thermal budget or distribution change can be reduced.

### Fourth Embodiment

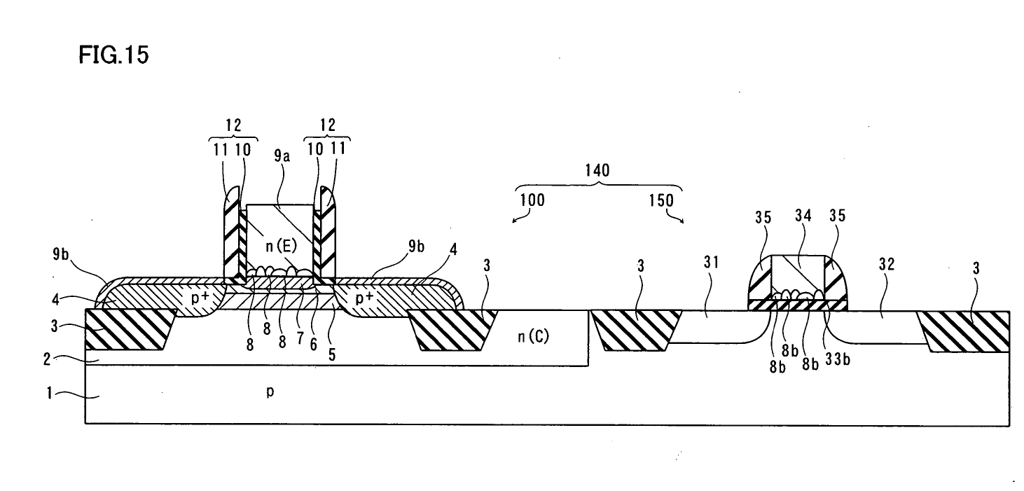

In a semiconductor device 140 according to a fourth embodiment, as shown in FIG. 15, reaction suppression layers 8b are formed in a field-effect transistor 150 dissimilarly to the aforementioned third embodiment.

In the field-effect transistor 150, a gate insulating film 33b containing SiON is formed on a surface of the silicon substrate 1. The reaction suppression layers 8b containing titanium nitride (TiN) are formed on a surface of the gate insulating film 33b. The reaction suppression layer 8b is an example of the “second reaction suppression layer” in the present invention. A gate electrode 34 containing a compound of a metal such as Ti, Co or Ni and a semiconductor such as Si or Ge is formed on a surface of the reaction suppression layers 8b. Side wall insulating films 35 are formed on side surfaces of the reaction suppression layers 8b and the gate electrode 34.

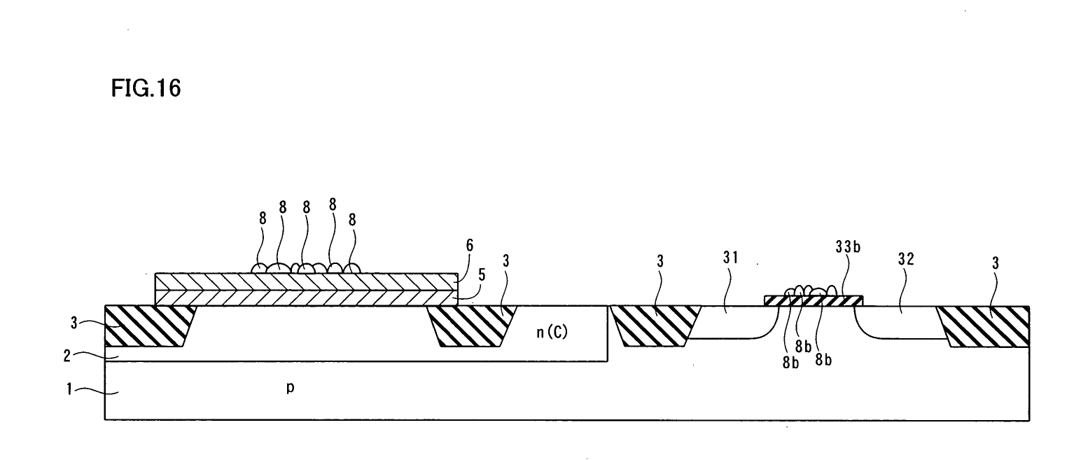

A process of fabricating the reaction suppression layers 8 and the reaction suppression layers 8b will be described with reference to FIG. 16.

The gate insulating film 33b containing SiO₂ is formed on a prescribed region of the silicon film 6 and prescribed regions of the impurity regions 31 and 32 by thermal oxidation.

The reaction suppression layers 8 containing titanium nitride (TiN) having a thickness of not more than about 20 nm, preferably not more than about 10 nm are formed on an overall surface of the silicon substrate 1 by low pressure CVD. The composition ratio of titanium (Ti) in TiN is about 45% to about 55%. In the reaction suppression layers 8, a surface of a thin film is not flat and is preferably constituted by a polycrystalline or nanocrystalline material formed by crystal grains each having a grain size of about 1 nm to about 10 nm. More particularly, the polycrystalline or nanocrystalline material is more preferably formed by crystal grains each having a grain size of about 1 nm to about 3 nm. As shown in FIG. 16, prescribed regions of the reaction suppression layers 8 formed on the overall surface of the silicon substrate 1 are removed by RIE. Thus, the reaction suppression layers 8 formed on a surface of the silicon film 6 and the reaction suppression layers 8b formed on the surface of the gate insulating film 33b are formed in the same step.

According to the fourth embodiment, as hereinabove described, the reaction suppression layers 8b are provided between the gate insulating film 33b and the gate electrode 34, whereby the gate electrode 34 can be inhibited from depletion. This structure is formed through the same step as that of the reaction suppression layers 8, whereby the cost can be reduced.

### Fifth Embodiment

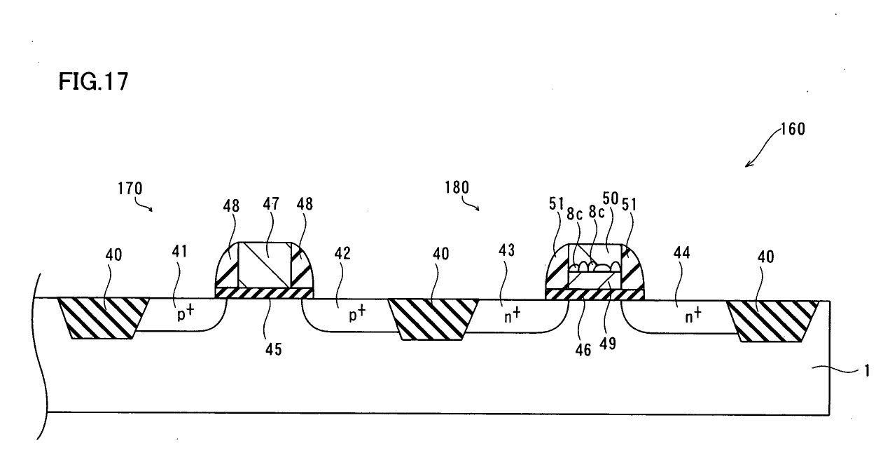

In a semiconductor device 160 according to a fifth embodiment, as shown in FIG. 17, a p-type field-effect transistor 170 and an n-type field-effect transistor 180 are so formed as to be adjacent to a bipolar transistor (now shown) dissimilarly to the aforementioned first embodiment.

In the semiconductor device 160, element isolation regions 40 employing STI, for isolating the bipolar transistor 170 and the field-effect transistor 180 are formed on a surface of a silicon substrate 1. In the field-effect transistor 170, p⁺-type impurity regions 41 and 42 serving as source/drain of the field-effect transistor 170 are so formed on the surface of the silicon substrate 1 at a prescribed interval as to hold a channel region therebetween.

In the field-effect transistor 180, n⁺-type impurity regions 43 and 44 serving as source/drain of the field-effect transistor 180 are so formed on the surface of the silicon substrate 1 at a prescribed interval as to hold a channel region therebetween.

A gate insulating film 45 containing HfON is formed on a region formed with the field-effect transistor 170 on the surface of the silicon substrate 1, and a gate insulating film 46 containing HfON is formed on a region formed with the field-effect transistor 180 on the surface of the silicon substrate 1.

A gate electrode 47 silicided by platinum (Pt) is formed on a surface of the gate insulating film 45. Side wall insulating films 48 are formed on side surfaces of the gate electrode 47.

A semiconductor layer 49 is formed on a surface of the gate insulating film 46. The semiconductor layer 49 is an example of the “third semiconductor layer” in the present invention. Reaction suppression layers 8c containing titanium nitride (TiN) is formed on a surface of the semiconductor layer 49. The reaction suppression layers 8c is an example of the “second reaction suppression layer” in the present invention. The reaction suppression layers 8 formed in the bipolar transistor 100 and the reaction suppression layers 8c formed in the field-effect transistor 180 are formed in the same step. A gate electrode 50 silicided by platinum (Pt) is formed on a surface of the reaction suppression layers 8c. Side wall insulating films 51 are formed on side surfaces of the semiconductor layer 49, the reaction suppression layers 8c and the gate electrode 50.

HfOₓ having a potential as a high dielectric constant gate insulating film has the work function of Si or silicide Fermi-level pinned on a side closer to a conduction band, and the threshold voltage (Vt) of the p-type field-effect transistor is increased, thereby likely to hinder low voltage drive of a device. As a method to avoid this, a method of forming metal-rich silicide in the gate electrode and forming silicide having a large metal composition ratio on the gate insulating film is known. Thus, the effective work function of the gate can be controlled to a value near a work function of an original metal.

According to the fifth embodiment, as hereinabove described, the gate electrode 47 of the p-type field-effect transistor 170 is silicided by platinum in the semiconductor device 160, whereby a depletion layer can be easily inhibited from being generated in the gate electrode 47 and the work function for the gate of the p-type field-effect transistor 170 can be accomplished. The reaction suppression layers 8c are provided in the n-type field-effect transistor 180, whereby a region from the surface of the gate electrode 50 to the reaction suppression layers 8c are silicided and hence a depletion layer can be inhibited from being generated in the gate electrode 50. In the semiconductor layer 49 under the reaction suppression layers 8c, silicide having smaller metal composition ratio as compared with the gate electrode 50 is formed and hence the work function for the gate of the n-type field-effect transistor 180 can be easily accomplished.

Although the present invention has been described and illustrated in detail, it is clearly understood that the same is by way of illustration and example only and is not to be taken by way of limitation, the spirit and scope of the present invention being limited only by the terms of the appended claims.

For example, while the reaction suppression layers containing titanium nitride (TiN) are formed in each of the aforementioned first to fifth embodiment, the present invention is not restricted to this but the reaction suppression layers containing tantalum nitride (TaN) may be alternatively formed.

While the cobalt (Co) silicide film obtained by silicidation of silicon and cobalt is formed as the emitter electrode (cobalt silicide film 9a) in each of the aforementioned first to fifth embodiment, the present invention is not restricted to this but a silicide film obtained by silicidation of titanium (Ti) or nickel (Ni) and silicon may be alternatively formed.

While the cobalt (Co) silicide film obtained by silicidation of silicon and cobalt is formed as the emitter electrode (cobalt silicide film 9a) in each of the aforementioned first to fifth embodiment, the present invention is not restricted to this but an emitter electrode may alternatively formed by silicidation of metal and silicon, or an emitter electrode may be alternatively formed by employing germanium (Ge) in place of silicon.

What is claimed is:

1. A semiconductor device comprising:
an emitter layer;
an emitter electrode containing a metal-semiconductor compound of a metal and a semiconductor, formed on a surface of said emitter layer; and
a first reaction suppression layer formed between said emitter layer and said emitter electrode and suppressing permeation of said metal diffused from said emitter electrode.

2. The semiconductor device according to claim 1, wherein
said metal-semiconductor compound contains a metal silicide.

3. The semiconductor device according to claim 1, wherein
said first reaction suppression layer contains tantalum nitride (TaN) or titanium nitride (TiN).

4. The semiconductor device according to claim 3, wherein
said first reaction suppression layer is formed by a polycrystalline material or a nanocrystalline material.

5. The semiconductor device according to claim 1, further comprising a second semiconductor layer formed between said emitter layer and said first reaction suppression layer and containing an impurity.

6. The semiconductor device according to claim 1, further comprising:
a gate insulating film;
a gate electrode formed on a surface of said gate insulating film, and containing a metal-semiconductor compound made of the same material as that of said metal-semiconductor compound constituting said emitter electrode; and
a second reaction suppression layer formed between said gate insulating film and said gate electrode and suppressing permeation of a metal diffused from said gate electrode.

7. The semiconductor device according to claim 6, further comprising a third semiconductor layer formed between said gate insulating film and said second reaction suppression layer and containing an impurity.

8. The semiconductor device according to claim 6, wherein
said gate insulating film is a gate insulating film including a material containing a compound of Si, Al, Ti, Hf and N.

9. The semiconductor device according to claim 6, wherein
said emitter layer and said gate electrode contain a compound of a metal of Ti, Co or Ni and a semiconductor of Si or Ge.

10. The semiconductor device according to claim 6, wherein
said first reaction suppression layer and said second reaction suppression layer are formed by the same layer.

11. A method of fabricating a semiconductor device, comprising steps of:
forming an emitter layer;
forming a first reaction suppression layer suppressing permeation of a metal on a surface of said emitter layer; and
forming an emitter electrode containing a metal-semiconductor compound of a metal and a semiconductor on a surface of said first reaction suppression layer after forming said first reaction suppression layer.

12. The method of fabricating a semiconductor device according to claim 11, wherein said step of forming said emitter electrode containing said metal-semiconductor compound of said metal and said semiconductor includes a step of forming a silicon layer on said surface of said first reaction suppression layer and thereafter forming an emitter electrode containing a metal silicide by thermal reaction of said silicon layer and said metal.

13. The method of fabricating a semiconductor device according to claim 11, wherein
said first reaction suppression layer is formed by tantalum nitride (TaN) or titanium nitride (TiN).

14. The method of fabricating a semiconductor device according to claim 11, further comprising a step of forming a second semiconductor layer containing an impurity on said surface of said emitter layer in advance of said step of forming said first reaction suppression layer.

15. The method of fabricating a semiconductor device according to claim 11, further comprising steps of:
forming a gate insulating film;
forming a second reaction suppression layer suppressing permeation of a metal on a surface of said gate insulating film; and
forming a gate electrode containing a metal-semiconductor compound made of the same material as that of said metal-semiconductor compound constituting said emitter electrode on a surface of said second reaction suppression layer after forming said second reaction suppression layer.

16. The method of fabricating a semiconductor device according to claim 15, wherein
said first reaction suppression layer and said gate insulating film are formed through the same nitridation step.

17. The method of fabricating a semiconductor device according to claim 15, further comprising a step of forming a third semiconductor layer containing an impurity on a surface of said gate electrode in advance of said step of forming said second reaction suppression layer.

18. The method of fabricating a semiconductor device according to claim 15, wherein
said gate insulating film is a gate insulating film including a material containing a compound of Si, Al, Ti, Hf and N.

19. The method of fabricating a semiconductor device according to claim 15, wherein
said emitter layer and said gate electrode are formed by a compound of a metal of Ti, Co or Ni and a semiconductor of Si or Ge.

20. The method of fabricating a semiconductor device according to claim 15, wherein
said first reaction suppression layer and said second reaction suppression layer are formed through the same step.
